(19) United States
(12) Patent Application Publication
(10) Pub. No.: US 2024/0371831 A1
(43) Pub. Date: Nov. 7, 2024

(54) SEMICONDUCTOR APPARATUS USING BOTH SURFACES OF A WAFER AND MANUFACTURING METHOD OF THE SAME

(71) Applicant: Samsung Electronics Co., Ltd., Suwon-si (KR)

(72) Inventors: Joonho Jun, Suwon-si (KR); Duk Sung Kim, Suwon-si (KR); Gyesik Oh, Suwon-si (KR); Minwoo Lee, Suwon-si (KR); Wangyong Im, Suwon-si (KR); Byoungkon Jo, Suwon-si (KR)

(21) Appl. No.: 18/488,152

(22) Filed: Oct. 17, 2023

(30) Foreign Application Priority Data
May 2, 2023 (KR) 10-2023-0057039

(51) Int. Cl. H01L 25/065; H01L 23/00; H01L 23/538; H10B 80/00

(52) U.S. Cl. CPC H01L 25/0657; H01L 23/5386; H01L 24/08; H01L 24/16; H10B 80/00; H01L 2224/08145; H01L 2224/16225; H01L 2225/06517; H01L 2225/06541; H01L 2924/1431; H01L 2924/1434

(57) ABSTRACT

A semiconductor apparatus includes a semiconductor layer having a first surface and a second surface that is opposite to the first surface; a first wire structure on the first surface of the semiconductor layer; a second wire structure on the second surface of the semiconductor layer; a through via that extends through the semiconductor layer and is electrically connected to the first wire structure and the second wire structure; a first semiconductor element layer that is adjacent to the first surface of the semiconductor layer and in the semiconductor layer; and a second semiconductor element layer that is adjacent to the second surface of the semiconductor layer and in the semiconductor layer.

### CROSS-REFERENCE TO RELATED APPLICATION

This application claims priority to and the benefit of Korean Patent Application No. 10-2023-0057039 filed in the Korean Intellectual Property Office on May 2, 2023, the entire contents of which are incorporated herein by reference.

### TECHNICAL FIELD

The present disclosure relates to a hybrid semiconductor apparatus using both surfaces of a wafer and a manufacturing method thereof.

### BACKGROUND

As functions of electronic products become more complicated and a size of the electronic products is reduced, more semiconductor mounting per unit volume is required. To satisfy such a demand, a system on chip (SOP) or a system in package (SIP) may be used.

The system-on-chip (SOP) relates to a technology for manufacturing by integrating functions of a plurality of semiconductor chips into one semiconductor chip so that functions performed by several semiconductor chips may be performed in one semiconductor chip. The system in package (SIP) relates to a technology of integrating a plurality of individual semiconductor chips into one semiconductor package, and is a technology of packaging such that one semiconductor package operates as one system.

Despite these size reduction technologies, the demand for size reduction of the semiconductor apparatus is increasing.

### SUMMARY

An embodiment may provide a down-sized hybrid semiconductor apparatus that integrates and performs several functions.

Embodiments are not limited to the embodiment mentioned above, and other embodiments not mentioned will be clearly understood by those of ordinary skill in the art to which the embodiment belongs from the description below.

A semiconductor apparatus according to an embodiment may include a semiconductor layer having a first surface and a second surface that is opposite to the first surface; a first wire structure on the first surface of the semiconductor layer; a second wire structure on the second surface of the semiconductor layer; and a through via that extends through the semiconductor layer and is electrically connected to the first wire structure and the second wire structure; where the semiconductor layer includes a first semiconductor element layer that is adjacent to the first surface of the semiconductor layer; and where the semiconductor layer includes a second semiconductor element layer that is adjacent to the second surface of the semiconductor layer.

A semiconductor apparatus according to an embodiment may include a semiconductor layer having a first surface and a second surface that is opposite to the first surface; a first wire structure on the first surface of the semiconductor layer, where the first wire structure includes a plurality of first metal line layers, a plurality of first connection vias that electrically connect the plurality of first metal line layers to each other, and a plurality of first interlayer insulating layers that electrically isolate the plurality of first metal line layers from each other; a second wire structure on the second surface of the semiconductor layer, where the second wire structure includes a plurality of second metal line layers, a plurality of second connection vias that electrically connect the plurality of second metal line layers to each other, and a plurality of second interlayer insulating layers that electrically isolate the plurality of second metal line layers from each other; and a through via that extends through the semiconductor layer and that is electrically connected to the first wire structure and the second wire structure, where the semiconductor layer includes a first semiconductor element layer that is adjacent to the first surface of the semiconductor layer, and where the first semiconductor element layer and the first wire structure are configured to operate as a cache memory or a logic circuit, and the semiconductor layer includes a second semiconductor element layer that is adjacent to the second surface of the semiconductor layer, where the second semiconductor element layer and the second wire structure are configured to operate as a main memory.

A semiconductor apparatus according to an embodiment may include a semiconductor layer comprising a first surface and a second surface that is opposite to the first surface; a first wire structure on the first surface of the semiconductor layer, where the first wire structure comprises a plurality of first metal line layers, a plurality of first connection vias that electrically connect the plurality of first metal line layers to each other, and a plurality of first interlayer insulating layers that electrically isolate the plurality of first metal line layers from each other; a second wire structure on the second surface of the semiconductor layer, where the second wire structure comprises a plurality of second metal line layers, a plurality of second connection vias that electrically connect the plurality of second metal line layers to each other, and a plurality of second interlayer insulating layers that electrically isolate the plurality of second metal line layers from each other; a through via that extends through the semiconductor layer and that is electrically connected to the first wire structure and the second wire structure; and a logic die bonded to a surface of the first wire structure that is opposite to the first surface of the semiconductor layer, where the semiconductor layer comprises a first semiconductor element layer that is adjacent to the first surface of the semiconductor layer, where the first semiconductor element layer and the first wire structure are configured to operate as a logic circuit or a cache memory; and where the semiconductor layer comprises a second semiconductor element layer that is adjacent to the second surface of the semiconductor layer, where the second semiconductor element layer and the second wire structure are configured to operate as a main memory.

A manufacturing method of a semiconductor apparatus according to an embodiment may include forming a second semiconductor element layer around a first surface of a preliminary semiconductor layer having the first surface and a second surface opposite to the first surface; forming a second wire structure on the second semiconductor element layer; attaching a carrier substrate on the second wire structure; forming a semiconductor layer by cutting the second surface side of the preliminary semiconductor layer to reduce the thickness; forming a through hole in the semiconductor layer; forming a first semiconductor element layer around an second surface of the semiconductor layer exposed by cutting the second surface side of the preliminary semiconductor layer; and forming a first wire structure on the first semiconductor element layer.

According to an embodiment, the thickness and size of a semiconductor apparatus may be reduced by utilizing both surfaces of a semiconductor substrate.

In addition, according to an embodiment, a signal delay may be reduced by connecting electronic devices implemented on both surfaces of one semiconductor substrate through the through via.

### BRIEF DESCRIPTION OF THE DRAWINGS

FIG. 1 is a cross-sectional view of a semiconductor apparatus according to embodiments of the present disclosure.

FIGS. 2A, 2B, 2C, 2D, and 2E are cross-sectional views of various steps of a method for manufacturing a semiconductor apparatus according to embodiments of the present disclosure.

FIGS. 3, 4, 5, 6, and 7 are cross-sectional views of a semiconductor apparatus according to additional embodiments of the present disclosure.

### DETAILED DESCRIPTION OF THE EMBODIMENTS

Embodiments will be described more fully hereinafter with reference to the accompanying drawings. As those skilled in the art would realize, the described embodiments may be modified in various ways, all without departing from the spirit or scope of the embodiments.

The drawings and descriptions are to be regarded as illustrative in nature and not restrictive. Throughout the specification, same reference numerals refer to same constituent elements.

In the drawing, the size and thickness of each constituent element may be arbitrarily shown for better understanding and ease of description, and the present disclosure is not necessarily limited to what is shown in the drawing. In the drawing, a thickness of a layer, a film, a plate, a region, etc. may be exaggerated for clarity. In the drawing, the thickness of some layers and regions may be exaggerated for better understanding and ease of description.

The singular form used in this specification are intended to include the plural forms as well, unless the context clearly dictates otherwise.

In the specification and of claim range, a term “and/or” is intended to include any combination of the terms “and” and “or” for its meaning and interpretation. For example, “A and/or B” may be understood to mean “A, B, or A and B”.

The phrase “at least one of-” in the specification and scope of claims is intended to include the meaning of “at least one selected from the group of-” for its meaning and interpretation. For example, “at least one of A and B” may be understood to mean “A, B, or A and B”.

Although terms such as first, second, etc., may be used to describe diverse constituent elements, such constituent elements are not limited by the terms. The terms are used only to discriminate a constituent element from other constituent elements. For example, without departing from the scope of the present disclosure, a first constituent element may be named a second constituent element, and similarly, a second constituent element may also be named a first constituent element.

When an element such as a layer, film, region or substrate is referred to as being “on” another element, it may be directly on the other element or intermediate elements may also exist. In contrast, when an element is referred to as being “directly on” another element, there are no intermediate elements present. In addition, the term ‘above’ of the target element throughout the specification should be understood as positioning above or below the target element, and does not necessarily mean positioning ‘above’ with the opposite direction of gravity as a reference.

The spatially relative terms “below”, “above” may be used to describe a correlation between one element or constituent element and other elements or constituent elements as shown in the accompanying drawings.

Spatially relative terms are intended to include other directions in the device in use or operation in addition to the directions shown in the drawing. For example, if a device shown in the drawing is turned over, a device located ‘below’ another device may be located ‘above’ the other device. Thus, the exemplary term “below” may include both lower and upper positions. Devices may also be oriented in different directions, so spatially relative terms can be interpreted differently depending on the direction.

When an element (or a region, a layer, a portion, etc.) is referred to in the specification as being “connected” or “coupled” to another element, it either is directly disposed, connected, or coupled to the other element mentioned above, or intervening elements may be disposed between them.

The terms “connected to” or “coupled to” may include physical or electrical connections or couplings.

Unless otherwise defined, all terms (including technical and scientific terms) used in this specification have the same meaning as commonly understood by a person of an ordinary skill in the technical field to which the present disclosure belongs. It will be further understood that terms, such as those defined in commonly used dictionaries, should be interpreted as having a meaning that is consistent with their meaning in the context of the specification and claims and should not be interpreted in an idealized or overly formal sense unless expressly so defined herein.

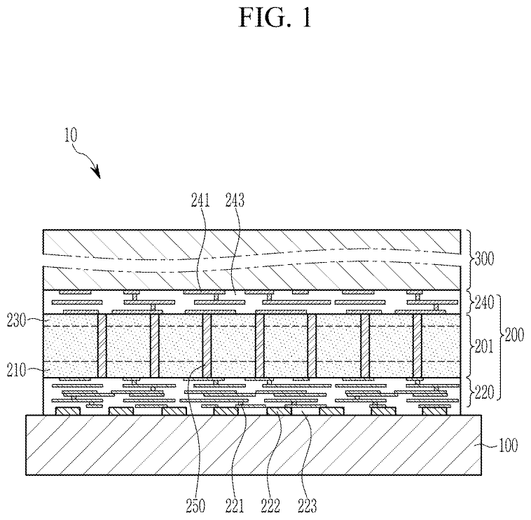

FIG. 1 is a cross-sectional view of a semiconductor apparatus 10 according to embodiments of the present disclosure.

Referring to FIG. 1, a hybrid chip 200 may be on a logic die 100, and a carrier substrate 300 may be on the hybrid chip 200. While a logic die 100 is shown, it should be understood that the logic die 100 may be replaced with a buffer die in other embodiments. The logic die 100 may perform operations such as sorting and outputting data collected from the hybrid chip 200. The hybrid chip 200 may be a chip having semiconductor devices performing different functions on upper and lower sides of one semiconductor layer respectively. The carrier substrate 300 may be a support substrate attached for manufacturing the hybrid chip 200.

The hybrid chip 200 may include a semiconductor layer 201 and a first wire structure 220 and a second wire structure 240 respectively on the upper and lower surfaces of the semiconductor layer 201.

The semiconductor layer 201 may include a first semiconductor element layer 210 that extends from the lower surface of the semiconductor layer 201 by a predetermined distance, and a second semiconductor element layer 230 that extends from the upper surface of the semiconductor layer 201 by a predetermined distance. The semiconductor layer 201 may be, for example, a silicon single crystal wafer, a silicon epitaxial layer, or a silicon on insulator (SOI) substrate. The first semiconductor element layer 210 and the second semiconductor element layer 230 may include a region in which the semiconductor layer 201 is doped with an impurity, such as P-type or N-type, an insulator formed by oxidizing or removing a part of the semiconductor layer 210, and a polysilicon structure or a metal structure that is separately formed. The first semiconductor element layer 210 and the second semiconductor element layer 230 may respectively include electronic elements that are configured to perform different functions. For example, the first semiconductor element layer 210 and the first wire structure 220 may be configured to operate as a cache memory and/or a logic circuit, and the second semiconductor element layer 230 and the second wire structure 240 may be configured to operate as a main memory, such as DRAM, SRAM, PRAM, NAND flash.

The semiconductor layer 201 may include a plurality of through vias 250 that extend through the semiconductor layer 201 and are connected to the first wire structure 220 and the second wire structure 240. For example, a through via 250 may penetrate through the semiconductor layer 201 to connect the first wire structure 220 and the second wire structure 240. The first semiconductor element layer 210 and the second semiconductor element layer 230 may be electrically connected to each other to exchange data signals by the through via 250, thereby reducing a signal delay. The through via 250 may include an insulation layer that electrically isolates the semiconductor layer 201 and a metal via.

The first wire structure 220 may include a metal line 221 that includes a plurality of metal line layers and a plurality of connection vias that connect the metal line layers, a plurality of interlayer insulating layers 223 that electrically isolate the plurality of metal line layers, and a conductive pad 222 that is located at the bottom of the first wire structure 220 and exposed to the outside of the hybrid chip 200. The conductive pad 222 may electrically connect the hybrid chip 200 to the logic die 100 when bonded to a conductive pad disposed on the logic die 100. The conductive pad 222 and the conductive pad of the logic die 100 may include copper (Cu), and the bonding may be a copper to copper (Cu to Cu) bonding. The metal line 221 may include a metal, such as copper or tungsten. The first wire structure 220 may electrically connect elements in the first semiconductor element layer 210 and may be electrically connected to the first semiconductor element layer 210 and the logic die 100. The first wire structure 220 may electrically connect the second semiconductor element layer 230 and the first semiconductor element layer 210 to the through via 250 and the second wire structure 240. The first wire structure 220 may electrically connect the second semiconductor element layer 210 and the logic die 100 to the through via 250 and the second wire structure 240.

The second wire structure 240 may include a metal line 241 that includes a plurality of metal line layers and a plurality of connection vias that connect the metal line layers, a plurality of interlayer insulating layers 243 that electrically isolate the plurality of metal line layers and a plurality of connection vias, and the like. The metal line 241 may include a metal, such as copper or tungsten. The second wire structure 240 may electrically connect elements within the second semiconductor element layer 230. The second wire structure 240 may electrically connect the second semiconductor element layer 230 and the first semiconductor element layer 210 to the through via 250 and the first wire structure 220. The second wire structure 240 may electrically connect the second semiconductor element layer 230 and the logic die 100 to the through via 250 and the first wire structure 220.

As described above, if the semiconductor devices having different functions are on upper and lower sides of a semiconductor layer 201 and connected to each other through the through via 250, the thickness and size of the entire semiconductor apparatus may be reduced, and a signal delay may also be reduced during the operation of the semiconductor apparatus.

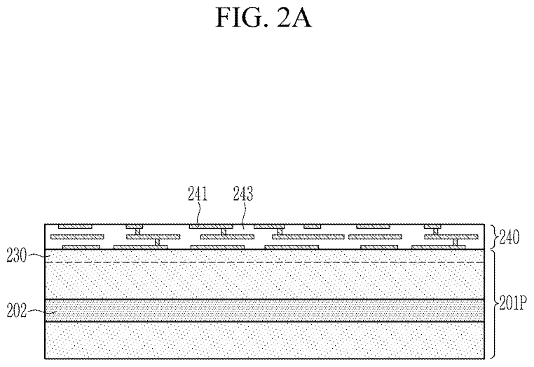

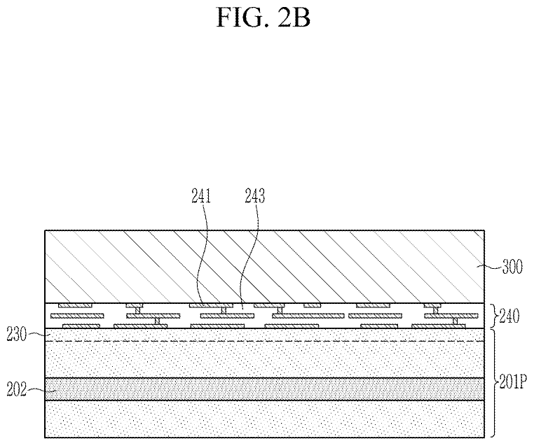

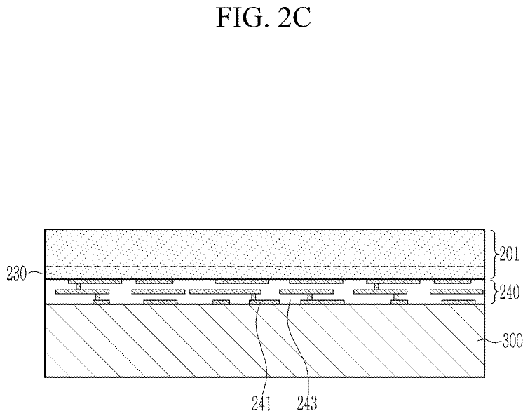

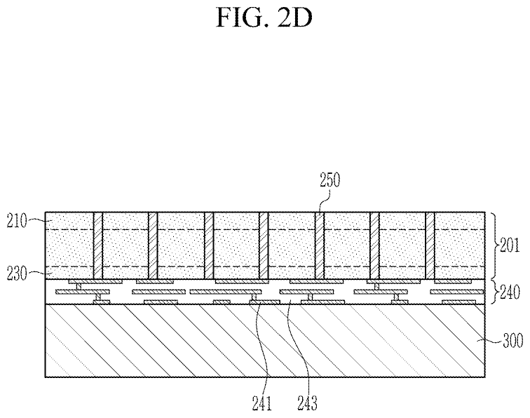

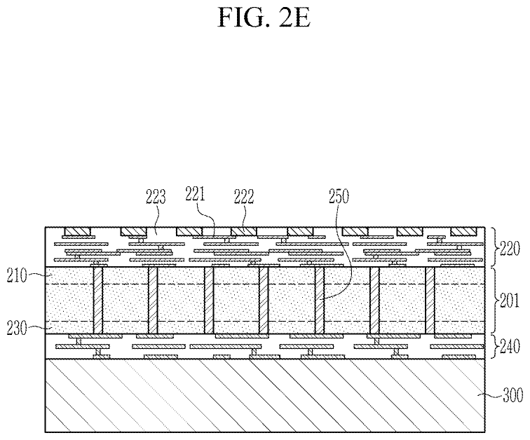

A method of the semiconductor apparatus according to an embodiment is described with reference to FIG. 2A to FIG. 2E. FIG. 2A to FIG. 2E are cross-sectional views at an intermediate stage of manufacturing a semiconductor apparatus according to an embodiment.

First, referring to FIG. 2A, a second semiconductor element layer 230 may be formed and a second wire structure 240 may be formed on the second semiconductor element layer 230 by applying a semiconductor manufacturing process to one side of a preliminary semiconductor layer 201P. The preliminary semiconductor layer 201P may have a structure in which a compound semiconductor layer 202, for example, a silicon germanium (SiGe) layer is sandwiched between two silicon layers. However, the preliminary semiconductor layer 201P may be a silicon single layer in other embodiments.

Next, and referring to FIG. 2B, a carrier substrate 300 may be attached to the second wire structure 240.

Next, and referring to FIG. 2C, the semiconductor layer 201 may be formed by inverting the entire structure to which the carrier substrate 300 is attached and removing the compound semiconductor layer 202 of the preliminary semiconductor layer 201P by wet etching. In some embodiments, the process of reducing the thickness of the preliminary semiconductor layer 201P may be performed using a mechanical chemical polishing (CMP).

Next, and referring to FIG. 2D, a through via 250 may be formed by forming a hole that extends through the semiconductor layer 201, forming an insulation layer on the surface of the hole, and filling the hole with a conductive material, such as a metal. Subsequently, a first semiconductor element layer 210 may be formed by applying a semiconductor manufacturing process to the other side of the semiconductor layer 201. In some embodiments, the through via 250 may be formed after forming the first semiconductor element layer 210.

Next, and referring to FIG. 2E, a first wire structure 220 may be formed on the first semiconductor element layer 210.

Next, and referring to FIG. 1, a semiconductor apparatus according to an embodiment may be manufactured by aligning and bonding the conductive pad 222 of the first wire structure 220 to the conductive pad of the logic die 100. The bonding method may be a copper-to-copper bonding method that applies heat and/or pressure.

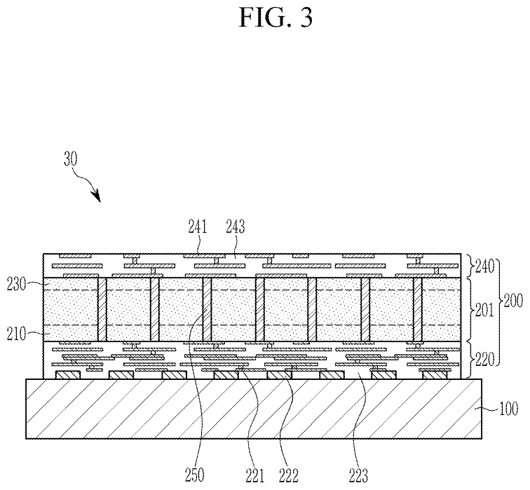

FIG. 3 is a cross-sectional view of a semiconductor apparatus 30 according to another embodiment of the present disclosure.

The semiconductor apparatus 30 is similar to the semiconductor apparatus 10 of FIG. 1, except that it does not include the carrier substrate 300. That is, the semiconductor apparatus 30 be a structure in which the carrier substrate 300 is separated and removed after manufacturing the semiconductor apparatus 10 of FIG. 1.

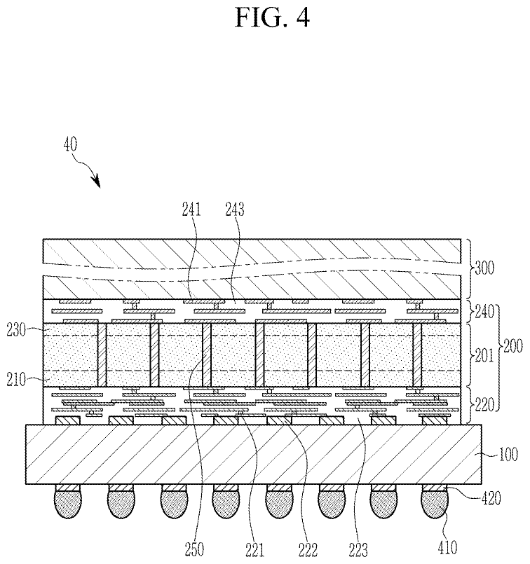

FIG. 4 is a cross-sectional view of a semiconductor apparatus 40 according to another embodiment of the present disclosure.

The semiconductor apparatus of 40 is similar to the semiconductor apparatus 10 of FIG. 1, except that the conductive pad 420 and the micro bump 410 are on a lower surface of the logic die 100. The semiconductor apparatus 40 may be mounted on another circuit board or an interposer by using the conductive pad 420 and the micro bump 410.

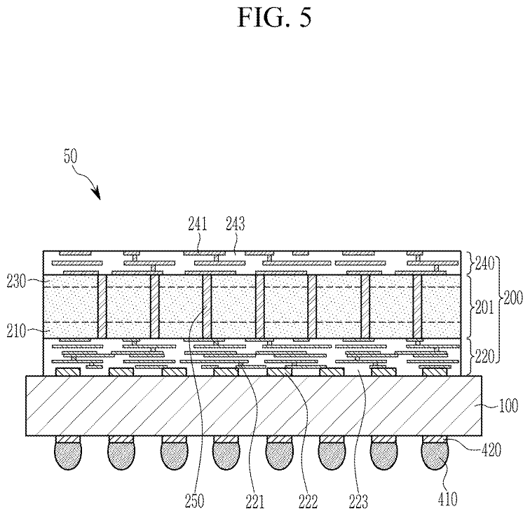

FIG. 5 is a cross-sectional view of a semiconductor apparatus 50 according to another embodiment of the present disclosure.

The semiconductor apparatus 50 is similar to the semiconductor apparatus 40 of FIG. 4, except that it does not include the carrier substrate 300. That is, the semiconductor apparatus 30 may be a structure in which the carrier substrate 300 is separated and removed after manufacturing the semiconductor apparatus 40 of FIG. 4.

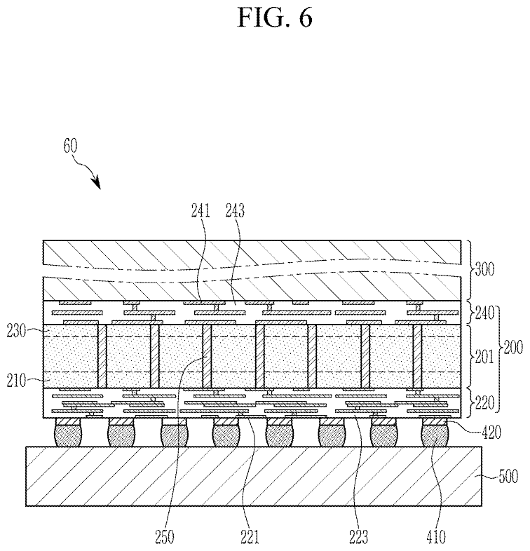

FIG. 6 is a cross-sectional view of a semiconductor apparatus according to another embodiment of the present disclosure.

The semiconductor apparatus 60 does not include logic die 100, and the conductive pad 420 exposed to the outside of the hybrid chip 200 and the micro bump 410 are below the first wire structure 220. The semiconductor apparatus of FIG. 6 may be mounted on the mounting substrate 500 by using the micro bump 410. The mounting substrate 500 may be a circuit board or an interposer. This structure may be more suitable when the first semiconductor element layer 210 and the first wire structure 220 operate as a logic die.

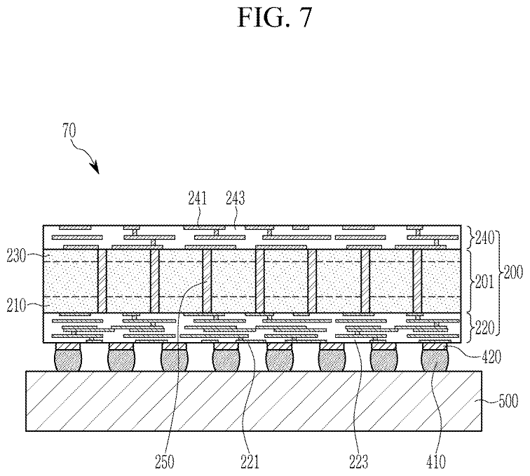

FIG. 7 is a cross-sectional view of a semiconductor apparatus according to another embodiment of the present disclosure.

The semiconductor apparatus of FIG. 7, compared to the semiconductor apparatus of FIG. 6, is different in that it does not have the carrier substrate 300. That is, the semiconductor apparatus 70 may be a structure in which the carrier substrate 300 is separated and removed after manufacturing the semiconductor apparatus 60 of FIG. 6.

As described above, when the semiconductor devices having different functions are on upper and lower sides of one semiconductor layer 201 and connected to each other through the through via 250, the thickness and size of the entire semiconductor apparatus may be reduced, and a signal delay may also be reduced during the operation of the semiconductor apparatus.

The embodiments are not limited to thereto, but may be manufactured in a variety of different forms, and those of ordinary skill in the art to which the embodiments pertains will understand that the embodiments may be implemented in other specific forms without changing the technical spirit or essential features of the embodiments. Therefore, it should be understood that the above-mentioned embodiments are exemplary in all aspects but are not limited thereto.

What is claimed is:

1. A semiconductor apparatus comprising:
a semiconductor layer comprising a first surface and a second surface that is opposite to the first surface;
a first wire structure on the first surface of the semiconductor layer;
a second wire structure on the second surface of the semiconductor layer; and
a through via that extends through the semiconductor layer and is electrically connected to the first wire structure and the second wire structure,
wherein the semiconductor layer comprises a first semiconductor element layer that is adjacent to the first surface of the semiconductor layer, and
wherein the semiconductor layer comprises a second semiconductor element layer that is adjacent to the second surface of the semiconductor layer.

2. The semiconductor apparatus of claim 1, further comprising:
a logic die on a surface of the first wire structure that is opposite to the first surface of the semiconductor layer.

3. The semiconductor apparatus of claim 2, further comprising:
a carrier substrate on a surface of the second wire structure that is opposite to the second surface of the semiconductor layer.

4. The semiconductor apparatus of claim 2, wherein:
the first wire structure includes a conductive pad on the surface of the first wire structure.

5. The semiconductor apparatus of claim 2, wherein:
the first wire structure and the second wire structure each comprises a plurality of metal line layers, a plurality of connection vias that electrically connect the plurality of metal line layers to each other, and a plurality of interlayer insulating layers that electrically isolate the plurality of metal line layers from each other.

6. The semiconductor apparatus of claim 2, further comprising:
a plurality of micro bumps on a surface of the logic die that is opposite to the surface of the first wire structure.

7. The semiconductor apparatus of claim 6, further comprising:
a carrier substrate on a surface of the second wire structure that is opposite to the second surface of the semiconductor layer.

8. The semiconductor apparatus of claim 1, further comprising:
a plurality of micro bumps on a surface of the first wire structure that is opposite to the first surface of the semiconductor layer.

9. The semiconductor apparatus of claim 8, further comprising:
a carrier substrate on a surface of the second wire structure that is opposite to the second surface of the semiconductor layer.

10. The semiconductor apparatus of claim 9, further comprising:
a mounting substrate on the plurality of micro bumps.

11. The semiconductor apparatus of claim 10, wherein:
the mounting substrate is a circuit board or an interposer.

12. The semiconductor apparatus of claim 8, further comprising:
a mounting substrate on the plurality of micro bumps.

13. The semiconductor apparatus of claim 12, wherein:
the mounting substrate is a circuit board or an interposer.

14. The semiconductor apparatus of claim 1, further comprising:
a carrier substrate on a surface of the second wire structure that is opposite to the second surface of the semiconductor layer.

15. The semiconductor apparatus of claim 1, wherein:
the first semiconductor element layer and the first wire structure are configured to operate as a cache memory, and the second semiconductor element layer and the second wire structure are configured to operate as a main memory.

16. The semiconductor apparatus of claim 1, wherein:
the first semiconductor element layer and the first wire structure are configured to operate as a logic circuit, and the second semiconductor element layer and the second wire structure are configured to operate as a memory.

17. A semiconductor apparatus comprising:
a semiconductor layer comprising a first surface and a second surface that is opposite to the first surface;
a first wire structure on the first surface of the semiconductor layer, wherein the first wire structure comprises a plurality of first metal line layers, a plurality of first connection vias that electrically connect the plurality of first metal line layers to each other, and a plurality of first interlayer insulating layers that electrically isolate the plurality of first metal line layers from each other;
a second wire structure on the second surface of the semiconductor layer, wherein the second wire structure comprises a plurality of second metal line layers, a plurality of second connection vias that electrically connect the plurality of second metal line layers to each other, and a plurality of second interlayer insulating layers that electrically isolate the plurality of second metal line layers from each other; and
a through via that extends through the semiconductor layer and that is electrically connected to the first wire structure and the second wire structure,
wherein the semiconductor layer comprises a first semiconductor element layer that is adjacent to the first surface of the semiconductor layer, wherein the first semiconductor element layer and the first wire structure are configured to operate as a cache memory or a logic circuit, and
wherein the semiconductor layer comprises a second semiconductor element layer that is adjacent to the second surface of the semiconductor layer, wherein the second semiconductor element layer and the second wire structure are configured to operate as a main memory.

18. The semiconductor apparatus of claim 17, further comprising:
a logic die on a surface of the first wire structure that is opposite to the first surface of the semiconductor layer; and
a carrier substrate on a surface of the second wire structure that is opposite to the second surface of the semiconductor layer.

19. The semiconductor apparatus of claim 18, further comprising:
a plurality of micro bumps on a surface of the logic die that is opposite to the surface of the first wire structure.

20. A semiconductor apparatus comprising:
a semiconductor layer comprising a first surface and a second surface that is opposite to the first surface;
a first wire structure on the first surface of the semiconductor layer, wherein the first wire structure comprises a plurality of first metal line layers, a plurality of first connection vias that electrically connect the plurality of first metal line layers to each other, and a plurality of first interlayer insulating layers that electrically isolate the plurality of first metal line layers from each other;
a second wire structure on the second surface of the semiconductor layer, wherein the second wire structure comprises a plurality of second metal line layers, a plurality of second connection vias that electrically connect the plurality of second metal line layers to each other, and a plurality of second interlayer insulating layers that electrically isolate the plurality of second metal line layers from each other;
a through via that extends through the semiconductor layer and that is electrically connected to the first wire structure and the second wire structure; and
a logic die bonded to a surface of the first wire structure that is opposite to the first surface of the semiconductor layer,
wherein the semiconductor layer comprises a first semiconductor element layer that is adjacent to the first surface of the semiconductor layer, wherein the first semiconductor element layer and the first wire structure are configured to operate as a logic circuit or a cache memory; and
wherein the semiconductor layer comprises a second semiconductor element layer that is adjacent to the second surface of the semiconductor layer, wherein the second semiconductor element layer and the second wire structure are configured to operate as a main memory.
